(19) United States
(12) Patent Application Publication
(10) Pub. No.: US 2026/0262239 A1
(43) Pub. Date: Sep. 3, 2026

(54) METHOD FOR MANUFACTURING THIN FILM TRANSISTOR, SPUTTERING TARGET, AND SINTERED BODY

(71) Applicant: KOBELCO RESEARCH INSTITUTE, INC., Hyogo (JP)

(72) Inventor: Mototaka OCHI, Kobe-shi (JP)

(73) Assignee: KOBELCO RESEARCH INSTITUTE, INC., Hyogo (JP)

(21) Appl. No.: 19/474,616

(22) PCT Filed: Mar. 12, 2024
(86) PCT No.: PCT/JP2024/009593

§ 371 Date: Oct. 10, 2025

(30) Foreign Application Priority Data
Apr. 18, 2023 (JP) 2023-068149
Feb. 6, 2024 (JP) 2024-016439

(51) Int. Cl. H10D 30/01; C23C 14/34; H10D 30/67; H10P 14/20; H10P 14/22; H10W 20/00; H10W 20/45

(52) U.S. Cl. CPC H10D 30/0314; C23C 14/3414; H10P 14/22; H10P 14/3434; H10P 14/3454; H10W 20/075; H10D 30/6731; H10D 30/6756; H10W 20/455

(57) ABSTRACT

An object of the present disclosure is to provide a method for manufacturing a thin film transistor that enables enhancing operational stability. An aspect of the present disclosure is a method for manufacturing a thin film transistor on a substrate, the thin film transistor including at least: an oxide semiconductor layer; a protective layer; a gate insulating layer; a gate electrode; a source electrode; and a drain electrode, the method including: forming on the substrate, the oxide semiconductor layer containing In, Zn, and Al as metal elements; and forming on the oxide semiconductor layer, the protective layer containing SiN.

### TECHNICAL FIELD

The present disclosure relates to a method for manufacturing a thin film transistor, and a sputtering target and a sintered body.

### BACKGROUND ART

Thin film transistors (TFTs) are becoming more common as active elements for use in flat panel displays such as organic EL (organic electro-luminescence) displays. As these thin film transistors, a top gate type (staggered type) and a bottom gate type (inverted staggered type) are well known.

Such thin film transistors are required to have operational stability. A thin film transistor having improved operational stability, increased carrier mobility, and improved light stress stability is known (Japanese Unexamined Patent Application, Publication No. 2020-194945).

### PRIOR ART DOCUMENTS

### Patent Documents

Patent Document 1: Japanese Unexamined Patent Application, Publication No. 2020-194945

### SUMMARY OF THE INVENTION

### Problems to be Solved by the Invention

The thin film transistor of Patent Document 1 has improved its operational stability by including an oxide semiconductor layer containing In, Zn, and Fe. In many thin film transistors, SiN is contained in protective layers. The protective layer containing SiN has a great content proportion of hydrogen, and the hydrogen may be desorbed and diffused from the protective layer due to thermal history in a manufacture process. When this hydrogen enters the oxide semiconductor layer of the thin film transistor, characteristics, such as a Vth shift, of the thin film transistor may deteriorate. Such deterioration of the characteristics has a great effect on a thin film transistor including an oxide semiconductor layer having high carrier mobility, and the operation tends to easily become unstable. It is required to reduce the effect of hydrogen and improve operational stability of a thin film transistor including an oxide semiconductor layer.

The present disclosure was made in view of the foregoing circumstances, and an object of the present disclosure is to provide: a method for manufacturing a thin film transistor that enables enhancing operational stability; and a sputtering target for forming an oxide semiconductor layer and an oxide gas barrier layer of a thin film transistor having high operational stability.

### Means for Solving the Problems

One aspect of the present disclosure is a method for manufacturing a thin film transistor on a substrate, the thin film transistor including at least: an oxide semiconductor layer; a protective layer; a gate insulating layer, a gate electrode; a source electrode; and a drain electrode, the method including: forming on the substrate, the oxide semiconductor layer containing In, Zn, and Al as metal elements; and forming on the oxide semiconductor layer, the protective layer containing SiN.

Another aspect of the present disclosure is a method for manufacturing a thin film transistor on a substrate, the thin film transistor including at least: an oxide semiconductor layer; an oxide gas barrier layer; a protective layer; a gate insulating layer; a gate electrode; a source electrode; and a drain electrode, the method including: forming the oxide semiconductor layer on the substrate; forming on the oxide semiconductor layer, the oxide gas barrier layer containing In, Zn, and Al as metal elements; and forming on the oxide gas barrier layer, the protective layer containing SiN.

Still another aspect of the present disclosure is a sputtering target for forming at least one of an oxide semiconductor layer and an oxide gas barrier layer to be used for a thin film transistor, the sputtering target containing: In, Zn, and Al as metal elements, wherein contents of the In, the Zn, and the Al with respect to a total of all metal elements contained are as follows: In: greater than or equal to 40 atm % and less than or equal to 75 atm %; Zn: greater than or equal to 15 atm % and less than or equal to 45 atm %; and Al: greater than or equal to 0.5 atm % and less than or equal to 20 atm %.

### Effects of the Invention

The method for manufacturing a thin film transistor, which is the one aspect of the present disclosure, enables enhancing operational stability of the thin film transistor. The sputtering target, which is the another aspect of the present disclosure, enables forming an oxide semiconductor layer and an oxide gas barrier layer of a thin film transistor having high operational stability.

### BRIEF DESCRIPTION OF THE DRAWINGS

FIG. 1 is a schematic cross-sectional view illustrating a top gate type thin film transistor according to an embodiment of the present disclosure.

FIG. 2 is a schematic cross-sectional view illustrating a top gate type thin film transistor different from that illustrated in FIG. 1.

FIG. 3 is a schematic cross-sectional view illustrating a top gate type thin film transistor different from those illustrated in FIGS. 1 and 2.

FIG. 4 is a graph showing measurement results of Id-Vg characteristics of a thin film transistor of sample 15 including an oxide semiconductor layer having a channel length of 10 μm and containing In and Zn.

FIG. 5 is a graph showing measurement results of Id-Vg characteristics of a thin film transistor of sample 16 including an oxide semiconductor layer having a channel length of 10 μm and containing In, Zn, and Al.

FIG. 6 is a graph showing results of comparison of light stress stability in accordance with a negative bias temperature illumination stress (NBTIS) test for which Id-Vg characteristics of the thin film transistor of sample 15 including the oxide semiconductor layer having a channel length of 10 μm and containing In and Zn were measured.

FIG. 7 is a graph showing results of comparison of light stress stability in accordance with the NBTIS test for which Id-Vg characteristics of the thin film transistor of sample 16 including the oxide semiconductor layer having a channel length of 10 μm and containing In, Zn, and Al were measured.

FIG. 8 is a graph showing measurement results of Id-Vg characteristics of each of thin film transistors including oxide semiconductor layers having different channel lengths and containing In and Zn.

FIG. 9 is a graph showing measurement results of Id-Vg characteristics of each of thin film transistors including oxide semiconductor layers having different channel lengths and containing In, Zn, and Al.

FIG. 10 is a graph showing measurement results of Id-Vg characteristics of a thin film transistor of sample 27 including an oxide semiconductor layer having a channel length of 10 μm and containing In, Zn, and Al.

FIG. 11 is a graph showing measurement results of Id-Vg characteristics of each of thin film transistors including oxide semiconductor layers having different channel lengths and containing In, Zn, and Al.

### MODE FOR CARRYING OUT THE INVENTION

### Description of Embodiments of Present Disclosure

First, embodiments of the present disclosure will be listed and described.

As described above, hydrogen (H) that has desorbed and diffused from a protective layer containing SiN may enter an oxide semiconductor layer, or this hydrogen may become water (H₂O) and the water (H₂O) may enter the oxide semiconductor layer, and thus characteristics, such as the Vth shift, of the thin film transistor may deteriorate. Thorough investigation by the present inventors revealed that: when an oxide semiconductor layer contains indium (In), zinc (Zn), and aluminum (Al), H₂ and H₂O can be inhibited from entering the oxide semiconductor layer; or when a thin film transistor includes an oxide gas barrier layer containing In, Zn, and Al, H₂ and H₂O can be inhibited from entering the oxide semiconductor layer. At the same time, it was revealed that the Al can inhibit desorption of Zn that may desorb from the inside of the layer due to aging or the like.
(1) The method for manufacturing a thin film transistor according to one aspect of the present disclosure is a method for manufacturing a thin film transistor on a substrate, the thin film transistor including at least: an oxide semiconductor layer, a protective layer; a gate insulating layer, a gate electrode; a source electrode; and a drain electrode, the method including: forming on the substrate, the oxide semiconductor layer containing In, Zn, and Al as metal elements; and forming on the oxide semiconductor layer, the protective layer containing SiN.

In the method for manufacturing the thin film transistor, because the oxide semiconductor layer containing In, Zn, and Al is formed on the substrate, H₂ and H₂O that have diffused can be inhibited from entering the oxide semiconductor layer, and operational stability of a thin film transistor to be obtained can be enhanced.
(2) The method for manufacturing a thin film according to another aspect of the present disclosure is a method for manufacturing a thin film transistor on a substrate, the thin film transistor including at least: an oxide semiconductor layer, an oxide gas barrier layer; a protective layer; a gate insulating layer, a gate electrode; a source electrode; and a drain electrode, the method including: forming the oxide semiconductor layer on the substrate; forming on the oxide semiconductor layer, the oxide gas barrier layer containing In, Zn, and Al as metal elements; and forming on the oxide gas barrier layer, the protective layer containing SiN.

In the method for manufacturing the thin film transistor, because the oxide gas barrier layer containing In, Zn, and Al is formed on the oxide semiconductor layer, H₂ and H₂O that have diffused can be inhibited from entering the oxide semiconductor layer, and operational stability of a thin film transistor to be obtained can be enhanced.
(3) In (2), the oxide semiconductor layer may contain In, Zn, and Al as metal elements. Accordingly, H₂ and H₂O can be more inhibited from diffusing into the oxide semiconductor layer.
(4) In (1), (2), and (3), content proportions of the metal elements with respect to a total thereof may be as follows: In: greater than or equal to 40 atm % and less than or equal to 75 atm %; Zn: greater than or equal to 15 atm % and less than or equal to 45 atm %; and Al: greater than or equal to 0.5 atm % and less than or equal to 20 atm %. Due to contents of the In, the Zn, and the Al in the metal elements falling within the ranges as described above, H₂ and H₂O can be effectively inhibited from entering the oxide semiconductor layer while optimization of carrier mobility and threshold voltage of the thin film transistor can be promoted.
(5) In (1), (2), and (3), the oxide semiconductor layer and the oxide gas barrier layer may each be an amorphous layer. Accordingly, the diffusion inhibition effect against H and H₂O can be improved.
(6) In (1) to (5), the oxide semiconductor layer and the oxide gas barrier layer may be each formed as a barrier layer against at least one of H₂ and H₂O. In other words, the oxide semiconductor layer itself may be formed as a layer that also serves as a gas barrier layer that inhibits the entering of at least one of H₂ and H₂O.
(7) In (1) to (6), the Al in the oxide semiconductor layer and in the oxide gas barrier layer may inhibit desorption of the Zn. In other words, the Al may be contained as a metal element that inhibits the desorption of the Zn.

The sputtering target according to still another aspect of the present disclosure is a sputtering target for forming at least one of an oxide semiconductor layer and an oxide gas barrier layer to be used for a thin film transistor, the sputtering target containing: In, Zn, and Al as metal elements, wherein contents of the In, the Zn, and the Al with respect to a total of all metal elements contained are as follows: In: greater than or equal to 40 atm % and less than or equal to 75 atm %; Zn: greater than or equal to 15 atm % and less than or equal to 45 atm %; and Al: greater than or equal to 0.5 atm % and less than or equal to 20 atm %.

The sputtering target enables forming the oxide semiconductor layer and the oxide gas barrier layer that can inhibit H₂ and H₂O from diffusing into the oxide semiconductor layer.

A sintered body according to yet another aspect of the present disclosure is a sintered body for forming the sputtering target.

In other words, the sputtering target may be formed of the sintered body.

### Details of Embodiments of the Present Disclosure

Hereinafter, embodiments of the present disclosure will be described in detail with reference to the drawings as appropriate. It is to be noted that with regard to numerical values described in the present specification, it is possible to adopt only one of an upper limit value and a lower limit value described, or to combine both an upper limit value and a lower limit value ad libitum. In the present specification, all numerical value ranges from upper limit values to lower limit values which may be combined are described as suitable ranges.

### First Embodiment

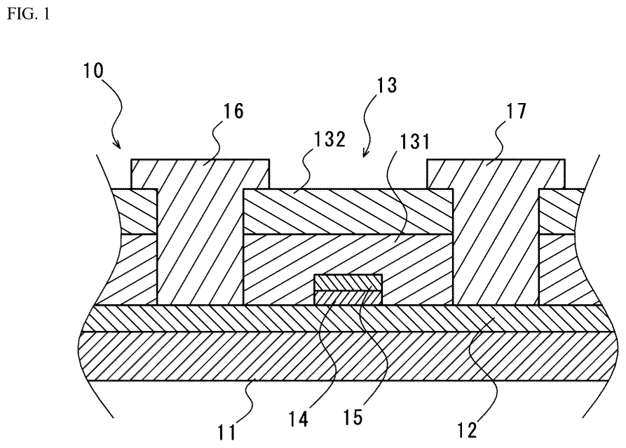

FIG. 1 illustrates a top gate type thin film transistor 10 (hereinafter, also be simply referred to as “thin film transistor 10”) as an example of a thin film transistor to be obtained by a method for manufacturing the thin film transistor (hereinafter, also be simply referred to as “the manufacture method”). The thin film transistor 10 includes on a substrate 11: an oxide semiconductor layer 12; a protective layer 13; a gate insulating layer 14; a gate electrode 15; a source electrode 16; and a drain electrode 17. The protective layer 13 of the thin film transistor 10 in FIG. 1 includes a first protective layer 131 containing silicon oxide (SiOx), and a second protective layer 132 laminated to the first protective layer 131 and containing silicon nitride (SiN). The gate insulating layer 14 and the gate electrode 15 are disposed in the protective layer 13 (first protective layer 131). The gate insulating layer 14 is laminated to the oxide semiconductor layer 12, and the gate electrode 15 is laminated to the gate insulating layer 14. The source electrode 16 and the drain electrode 17 are arranged so that a portion of each of the source electrode 16 and the drain electrode 17 is in contact with a conductive S/D region of the oxide semiconductor layer 12. A region of the oxide semiconductor layer 12 to which the gate insulating layer 14 is laminated is a channel region that is not conductive.

The thin film transistor 10 is obtained by the manufacture method including: a step of forming on the substrate 11, the oxide semiconductor layer 12 containing In, Zn, and Al as metal elements; and a step of forming on the oxide semiconductor layer 12, the protective layer 13 containing SiN. Between these two steps, the manufacture method includes a step of forming the gate insulating layer 14 on the oxide semiconductor layer 12, and a step of forming the gate electrode 15 on the gate insulating layer 14. After the step of forming the protective layer 13, the manufacture method also includes a step of forming the source electrode 16 and the drain electrode 17.

### Step of Forming Oxide Semiconductor Layer

In the step of forming the oxide semiconductor layer 12, the oxide semiconductor layer 12 containing In, Zn, and Al as metal elements is formed on the substrate 11.

### Substrate

The substrate 11 is not particularly limited, and is exemplified by a glass substrate, a silicon substrate, and the like. Examples of a glass to be used as the glass substrate include a non-alkali glass, a high strain point glass, a soda-lime glass, and the like. Furthermore, as the substrate 11, a metal substrate such as a stainless sheet, or a resin substrate such as a polyethylene terephthalate (PET) film may be used.

In light of processability, an average thickness of the substrate 11 is preferably greater than or equal to 0.001 mm and less than or equal to 10 mm. Furthermore, a size and a shape of the substrate 11 may be set in accordance with a size and the like of the display.

### Oxide Semiconductor Layer

The oxide semiconductor layer 12 contains In, Zn, and Al as metal elements. Due to containing these metal elements, the oxide semiconductor layer 12 can inhibit entering of H₂ therein which is diffused from the second protective layer 132 containing SiN, which will be described later. Furthermore, the oxide semiconductor layer 12 can also inhibit the diffused H₂ from binding to oxygen and entering as H₂O therein. In other words, the oxide semiconductor layer 12 has a function as a barrier layer against an H₂ gas and an H₂O gas.

### In

In is an element that inhibits H₂ and H₂O from entering the oxide semiconductor layer 12 and also contributes to improvement in electrical conductivity. As the content of In increases, the electrical conductivity of the oxide semiconductor layer 12 improves, and the carrier density and the carrier mobility improve.

The lower limit value of a content proportion of In with respect to a total of metal elements in the oxide semiconductor layer 12 is preferably 40 atm %. The upper limit value of the content proportion is preferably 75 atm %, and more preferably 65 atm %. The content proportion of In falling within the range enables improving certainty of an effect of inhibiting H₂ and H₂O from entering the oxide semiconductor layer 12, and allows for sufficient carrier mobility and the like.

### Zn

Zn is an element that inhibits H₂ and H₂O from entering the oxide semiconductor layer 12 and also affects processing characteristics of the oxide semiconductor layer 12.

The lower limit value of a content proportion of Zn with respect to a total of metal elements in the oxide semiconductor layer 12 is preferably 15 atm %, and more preferably 25 atm %. The upper limit value of the content proportion is preferably 45 atm %, and more preferably 35 atm %. The content proportion of Zn falling within the range enables improving certainty of the effect of inhibiting H₂ and H₂O from entering the oxide semiconductor layer 12, and facilitates securing processability, homogeneity, and/or the like of the oxide semiconductor layer 12.

### Al

Al is an element that inhibits H₂ and H₂O from entering the oxide semiconductor layer 12 and also inhibits desorption of Zn from the oxide semiconductor layer 12. Specifically, Zn may be desorbed from an inside of the oxide semiconductor layer 12 by aging or the like. Due to containing Al, the desorption of Zn can be inhibited. Furthermore, due to the oxide semiconductor layer 12 containing Al, light stress stability of the thin film transistor 10 can be improved.

The lower limit value of a content proportion of Al with respect to a total of metal elements in the oxide semiconductor layer 12 is preferably 0.5 atm %, and more preferably 1.5 atm %. The upper limit value of the content proportion is preferably 20 atm %, and more preferably 10 atm %. The content proportion of Al falling within the range enables improving certainty of the effect of inhibiting H₂ and H₂O from entering the oxide semiconductor layer 12, and enables improving certainty of an effect of inhibiting the desorption of Zn.

The reason why Al can inhibit the desorption of Zn is considered as follows. It is known that Zn in an oxide layer desorbs after H₂ or H₂O contained in the oxide layer is released. An oxide layer to which Al is added has a function (gas barrier function) of inhibiting H₂ or H₂O from entering the oxide layer, and also has a function of inhibiting H or H₂O in the oxide layer from being released. For this reason, it is considered that the desorption of Zn in the oxide layer can be inhibited by adding Al to the oxide layer.

In the oxide semiconductor layer 12, elements aside from those described above are O (oxygen) and inevitable impurities. The inevitable impurities may be contained owing to, e.g., raw materials, materials, manufacture equipment, and/or the like. Examples of these inevitable impurities include Pb, Si, Fe, Ni, Ti, Mg, Cr, and Zr. A content of the inevitable impurities in the oxide semiconductor layer 12 is preferably less than or equal to 1% by mass for each element, and more preferably less than or equal to 500 mass ppm. It is to be noted that in such a constitution, the content proportions of the In, the Zn, and the Al in the oxide semiconductor layer 12 may be also referred to as proportions accounted for in total elements aside from 0.

An average thickness of the oxide semiconductor layer 12 may be determined from conditions that allow a drain current to be turned off in a case of use as a switching element. The lower limit of the average thickness of the oxide semiconductor layer 12 is preferably 10 nm, and more preferably 15 nm. On the other hand, the upper limit of the average thickness is preferably 60 nm, and more preferably 50 nm. It is to be noted that the “average thickness” as referred to herein means an average value of thicknesses at 5 arbitrary points.

The oxide semiconductor layer 12 is preferably an amorphous layer. Alternatively, at least a part of the oxide semiconductor layer 12 is preferably formed as an amorphous layer. In other words, it is preferred that the oxide which forms the oxide semiconductor layer 12 is amorphous, or at least partly amorphous. Even in the case of having such a structure, the oxide semiconductor layer 12 enables sufficiently enhancing the carrier mobility compared to that of general-use amorphous silicon. Furthermore, when the oxide semiconductor layer 12 has such a structure, the optical band gap can be easily and reliably enlarged.

In general, as compactness of an oxide layer increases, the gas barrier function improves. The oxide layer composed of an amorphous material rather than a polycrystalline material in which a plurality of grain boundaries are present can have improved compactness. An In oxide has a gas barrier function, but tends to cause crystallization in the oxide layer. On the other hand, addition of Zn can promote making the oxide layer amorphous. Al may partly become an Al oxide by reacting with H₂O and thus tends to crystallize the part, but Al itself can promote making the oxide layer amorphous. Thus, it is considered that making the oxide layer amorphous is promoted due to the oxide layer containing In, Zn, and Al, whereby the oxide layer can exhibit a suitable gas barrier function against H₂ or H₂O.

By, for example, controlling gas pressure to fall within a range of greater than or equal to 1 mTorr and less than or equal to 5 mTorr and performing a surface treatment by means of plasma and/or reducing gas after film formation, the oxide semiconductor layer 12 can be made an amorphous layer.

The upper limit of a sheet resistance of the oxide semiconductor layer 12 (a sheet resistance of the S/D region after the surface treatment) is preferably 1.0 kΩ/□, and more preferably 0.5 kΩ/□. When the sheet resistance after the surface treatment is less than or equal to the upper limit, the oxide semiconductor layer 12 enables easily and reliably realizing making the S/D region conductive. It is to be noted that, as the sheet resistance, a value obtained by measurement using a four probe-type resistance measurement device can be employed.

The oxide semiconductor layer 12 is provided through film formation by means of a sputtering process using a sputtering target. The oxide semiconductor layer 12 is patterned by means of photolithography or the like after the film formation. Furthermore, immediately after this patterning, a heat treatment (pre-annealing treatment) is preferably performed for film quality improvement.

### Sputtering Target

The oxide semiconductor layer 12 can be formed from a sputtering target containing In, Zn, and Al as metal elements, wherein contents of the In, the Zn, and the Al with respect to a total of all metal elements contained are as follows: In: greater than or equal to 40 atm % and less than or equal to 75 atm %; Zn: greater than or equal to 15 atm % and less than or equal to 45 atm %; and Al: greater than or equal to 0.5 atm % and less than or equal to 20 atm %. Elements other than the above in the sputtering target are the inevitable impurities. The content of each element in the sputtering target can be set to fall within the same range as that described about the oxide semiconductor layer 12.

A sputtering target material to be formed into the sputtering target can be used to form the oxide semiconductor layer 12, and can also be used to form an oxide gas barrier layer described later. Since the sputtering target material contains the same metal elements as those of the sputtering target described above, and the contents are also substantially the same, the sputtering target material can have a gas barrier function against H₂ and H₂O.

### Sintered Body

The sputtering target is formed of a sintered body.

### Step of Forming Gate Insulating Layer

In the step of forming the gate insulating layer 14, the gate insulating layer 14 is formed on the oxide semiconductor layer 12. The gate insulating layer 14 is formed on the oxide semiconductor layer 12 after the above-described pre-annealing treatment.

Examples of the gate insulating layer 14 include: a silicon oxide layer; a silicon nitride layer; a silicon oxynitride layer, a metal oxide layer of Al₂O₃, Y₂O₃, or the like; and the like. The gate insulating layer 14 can be provided through film formation by using a CVD (chemical vapor deposition) procedure, a PECVD (plasma-enhanced chemical vapor deposition) procedure, or the like. The gate insulating layer 14 may be a monolayer body, or may be a multilayer body of two or more layers. In the case in which the gate insulating layer 14 is the multilayer body of two or more layers, it is preferred that a component of the first layer differs from those/that of the second and/or the following layer(s).

The lower limit of an average thickness of the gate insulating layer 14 is preferably 50 nm, and more preferably 100 nm. On the other hand, the upper limit of the average thickness of the gate insulating layer 14 is preferably 300 nm, and more preferably 250 nm. When the average thickness is less than the lower limit, pressure resistance of the gate insulating layer 14 may be insufficient. Conversely, when the average thickness is greater than the upper limit, capacitance of a capacitor formed between the gate electrode 15 and the oxide semiconductor layer 12 may be insufficient, and the drain current may be insufficient. It is to be noted that in the case in which the gate insulating layer 14 has multiple layers, the “average thickness of the gate insulating layer” as referred to means the average thickness of the total gate insulating layer.

### Step of Forming Gate Electrode

In the step of forming the gate electrode 15, the gate electrode 15 is formed on the gate insulating layer 14. The gate insulating layer 14 and the gate electrode 15 are patterned by means of photolithography or the like after forming of the gate electrode 15.

### Gate Electrode

The gate electrode 15 has electric conductivity. The gate electrode 15 is, for example, formed after forming the gate insulating layer 14, and after subjecting the oxide semiconductor layer 12 to the heat treatment (the annealing treatment). The gate electrode 15 is not particularly limited, and an alloy of: a metal having low electrical resistivity such as Al or Cu; a high-melting-point metal having superior heat resistance such as Mo, Cr, or Ti; or the like can be used.

The lower limit of an average thickness of the gate electrode 15 is preferably 50 nm, and more preferably 80 nm. When the average thickness is greater than or equal to the lower limit value, an increase in the resistance of the gate electrode 15 can be inhibited, whereby an increase in power consumption by the gate electrode 15 can be inhibited. On the other hand, in light of processability and the like, the upper limit of the average thickness of the gate electrode 15 is preferably 500 nm, and more preferably 400 nm.

### Step of Forming Protective Layer

In the step of forming the protective layer 13, the protective layer 13 containing SiN is formed on the oxide semiconductor layer 12. This step of the present embodiment includes: a procedure for forming on the oxide semiconductor layer 12, the first protective layer 131 containing SiOx so as to coat the gate insulating layer 14 and the gate electrode 15; and a procedure for forming on the first protective layer 131, the second protective layer 132 containing SiN.

The first protective layer 131 is formed after performing the surface treatment on the oxide semiconductor layer 12, following the patterning of the gate insulating layer 14 and the gate electrode 15. The surface treatment of the oxide semiconductor layer 12 is performed for the purpose of making the S/D region conductive, and can be performed by, e.g., ion implantation, element diffusion, reduction by a reducing gas, a plasma treatment, or the like.

The first protective layer 131 and the second protective layer 132 can be provided through film formation by using a CVD procedure, a PECVD procedure, or the like. After the film formation, contact holes for arranging the source electrode 16 and the drain electrode 17 are formed by means of photolithography or the like.

The first protective layer 131 contains SiOx, and the second protective layer 132 contains SiN. In other words, the first protective layer 131 is a silicon oxide layer, and the second protective layer 132 is a silicon nitride layer.

Providing the protective layer 13 enables reducing an influence that the oxide semiconductor layer 12, the gate electrode 15, and the like may suffer from an external environment. The second protective layer 132 containing SiN is suitable for reducing an influence of H₂O or the like. On the other hand, because the second protective layer 132 containing SiN contains much H₂, the H₂ may be released by thermal history in the manufacture process. When this released H₂ enters the oxide semiconductor layer 12, electrical properties of the thin film transistor 10 may deteriorate. Because the first protective layer 131 containing SiOx can inhibit the entering of H₂, the first protective layer 131 disposed between the oxide semiconductor layer 12 and the second protective layer 132 enables H₂ released from the second protective layer 132 to be inhibited from directly entering the oxide semiconductor layer 12. Because the thin film transistor 10 further includes the oxide semiconductor layer 12 having a gas barrier function, it is possible to further inhibit H₂ from entering the oxide semiconductor layer 12.

### Step of Forming Electrodes

In the step of forming the electrodes, the source electrode 16 and the drain electrode 17 are formed. Specifically, in the contact holes, the source electrode 16 and the drain electrode 17 are formed so that a part of each thereof is in contact with the S/D region of the oxide semiconductor layer 12. After the source electrode 16 and the drain electrode 17 are formed, they are patterned by means of photolithography or the like.

The source electrode 16 and the drain electrode 17 have electric conductivity. The source electrode 16 and the drain electrode 17 are not particularly limited, and metals having low electrical resistivity such as Al and Cu; high-melting-point metals having superior heat resistance such as Mo, Cr, and Ti; or an alloy of these can be used.

The source electrode 16 and the drain electrode 17 coat a part of the protective layer 13, and are packed into the contact holes. Due to being thus provided, the source electrode 16 and the drain electrode 17 electrically connect with the oxide semiconductor layer 12 at both ends of the channel region of the thin film transistor 10.

The lower limit of an average thickness of the source electrode 16 and the drain electrode 17 is preferably 100 nm, and more preferably 150 nm. When the average thickness is greater than or equal to the lower limit value, an increase in the resistance of the source electrode 16 and the drain electrode 17 can be inhibited, whereby an increase in power consumption can be inhibited. The upper limit of the average thickness of the source electrode 16 and the drain electrode 17 is desirably greater than the total thickness of the gate insulating layer 14 and the gate electrode 15, and is, for example, preferably 1,000 μm, and more preferably 800 μm.

### Advantages

The manufacture method includes: the step of forming on the substrate 11, the oxide semiconductor layer 12 containing In, Zn, and Al as metal elements; and the step of forming on the oxide semiconductor layer 12, the protective layer 13 containing SiN; therefore, H₂ diffused from the protective layer 13 by thermal history in the manufacture process can be inhibited from entering the oxide semiconductor layer 12. For this reason, the thin film transistor 10 to be obtained has high carrier mobility and superior operational stability.

The sputtering target is suitable for manufacture of the oxide semiconductor layer 12.

### Second Embodiment

Hereinafter, another embodiment of the method for manufacturing the thin film transistor will be described. It is to be noted that the same components as those in the first embodiment described above are given the same reference symbols, and description thereof is omitted.

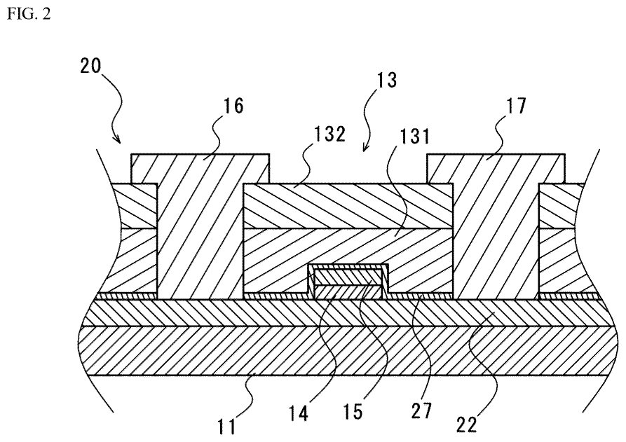

FIG. 2 illustrates a top gate type thin film transistor 20 (hereinafter, also be simply referred to as “thin film transistor 20”) to be obtained by a method for manufacturing the thin film transistor (hereinafter, also be simply referred to as “the manufacture method”). The thin film transistor 20 includes on a substrate 11: an oxide semiconductor layer 22; an oxide gas barrier layer 27; a protective layer 13; a gate insulating layer 14; a gate electrode 15; a source electrode 16; and a drain electrode 17. The protective layer 13 includes a first protective layer 131 containing SiOx, and a second protective layer 132 laminated to the first protective layer 131 and containing SiN.

The thin film transistor 20 includes: a step of forming the oxide semiconductor layer 22 on the substrate 11; a step of forming on the oxide semiconductor layer 22, the oxide gas barrier layer 27 containing In, Zn, and Al as metal elements; and a step of forming on the oxide gas barrier layer 27, the protective layer 13 containing SiN. Between the step of forming the oxide semiconductor layer and the step of forming the oxide gas barrier layer, the manufacture method includes: a step of forming the gate insulating layer 14 on the oxide semiconductor layer 22; and a step of forming the gate electrode 15 on the gate insulating layer 14. After the step of forming the protective layer 13, the manufacture method also includes a step of forming the source electrode 16 and the drain electrode 17.

### Step of Forming Oxide Semiconductor Layer

In the step of forming the oxide semiconductor layer, the oxide semiconductor layer 22 is formed on the substrate 11. A metal element contained in the oxide semiconductor layer 22 is not particularly limited, and the oxide semiconductor layer 22 may not contain any or all of In, Zn, and Al.

Next, the gate insulating layer 14 and the gate electrode 15 are formed on the oxide semiconductor layer 22.

### Step of Forming Oxide Gas Barrier Layer

In the step of forming the oxide gas barrier layer, the oxide gas barrier layer 27 containing In, Zn, and Al as metal elements is formed on the oxide semiconductor layer 22. Specifically, the oxide gas barrier layer 27 is formed so as to coat the gate insulating layer 14 and the gate electrode 15 formed on the oxide semiconductor 22.

The oxide gas barrier layer 27 contains In, Zn, and Al as metal elements. A content of each of the In, the Zn, and the Al with respect to a total of these metal elements can be set similarly to the oxide semiconductor layer 12 described in the first embodiment. The oxide gas barrier layer 27 is preferably an amorphous layer. Alternatively, at least a part of the oxide gas barrier layer 27 is preferably formed as an amorphous layer. The oxide gas barrier layer 27 has a function as a barrier layer against an H₂ gas and an H₂O gas. The Al inhibits desorption of the Zn from the oxide gas barrier layer 27.

### Step of Forming Protective Layer

In the step of forming the protective layer 13, the protective layer 13 containing SiN is formed on the oxide gas barrier layer 27. This step of the present embodiment includes: a procedure for forming on the oxide gas barrier layer 27, the first protective layer 131 containing SiOx; and a procedure for forming on the first protective layer 131, the second protective layer 132 containing SiN.

After the protective layer 13 is formed, contact holes are formed through the protective layer 13, and the source electrode 16 and the drain electrode 17 are formed in the contact holes.

### Advantages

The manufacture method includes: the step of forming the oxide semiconductor layer 22 on the substrate 11; the step of forming on the oxide semiconductor layer 22, the oxide gas barrier layer 27 containing In, Zn, and Al as metal elements; and the step of forming on the oxide gas barrier layer 27, the protective layer 13 containing SiN. In other words, the manufacture method enables obtaining the thin film transistor 20 in which the oxide gas barrier layer 27 containing In, Zn, and Al is formed between the oxide semiconductor layer 22 and the protective layer 13 containing SiN. For this reason, H₂ diffused from the protective layer 13 by thermal history in the manufacture process can be inhibited from entering the oxide semiconductor layer 22.

### Other Embodiments

The above-described embodiments are not to be construed as limiting the configuration of the present invention. Therefore, constituent elements of each part of the above-described embodiment may be omitted, replaced, or added based on the description in the present specification and common technical knowledge, and such omission, replacement, and addition should be construed as falling within the scope of the present invention.

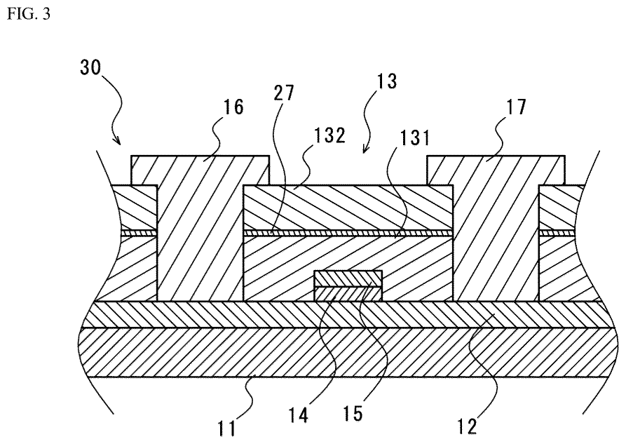

The oxide semiconductor layer of the thin film transistor (second embodiment) including the oxide gas barrier layer may contain In, Zn, and Al. Furthermore, as illustrated in FIG. 3, in a case in which an oxide semiconductor layer 12 containing In, Zn, and Al is used, an oxide gas barrier layer 27 of a thin film transistor 30 may be disposed in a protective layer 13 (between a first protective layer 131 and a second protective layer 132).

A specific configuration of the thin film transistor is not limited to the configurations shown in FIGS. 1, 2, and 3. For example, the protective layer may be only a protective layer containing SiN. Furthermore, the thin film transistor may be a bottom gate type.

Between the substrate and the oxide semiconductor layer, the thin film transistor may include another layer in order to improve adhesiveness, or, for example, a buffer layer as a buffer material.

### Examples

Hereinafter, the present invention is described in more detail by way of Examples, but the present invention is not to be construed as being limited to the descriptions of the following Examples.

Samples 1 to 14 were prepared for evaluating gas barrier resistance of an oxide layer containing In, Zn, and Al, against H₂ and H₂O. For each sample, a second protective layer (containing SiN) having a thickness of 150 nm was provided through film formation on a silicon substrate having a thickness of 525 μm; a first protective layer (containing SiO) having a thickness of 200 nm was provided through film formation on the second protective layer; and an oxide layer for which content proportions of In, Zn, and Al were changed was provided through film formation on the first protective layer.

Conditions for film formation and a thickness (film thickness) of the oxide layer of each sample are shown below.

### (1) Samples 1 to 12

Film forming procedure: DC (direct current) sputtering procedure
Apparatus: CS200, manufactured by ULVAC, Inc.
Film forming temperature: room temperature
Gas pressure: 1 mTorr
Carrier gas: Ar
Oxygen partial pressure: 100×O₂/(Ar+O₂)=4% by volume
Film forming power density: 2.55 W/cm²
Film thickness: 15 nm
(2) Samples 13 and 14
Film forming procedure: DC (direct current) sputtering procedure
Apparatus: CS200, manufactured by ULVAC, Inc.
Film forming temperature: room temperature
Gas pressure: 1 mTorr
Carrier gas: Ar
Oxygen partial pressure (first partial pressure): 100×O₂/(Ar+O₂)=0% by volume
Oxygen partial pressure (second partial pressure): 100×O₂/(Ar+O₂)=4% by volume
Film forming power density: 2.55 W/cm²
Film thickness: after 10 nm was formed at the first partial pressure, 15 nm was further formed at the second partial pressure (total 25 nm)

For each sample, gas barrier resistance was determined based on amounts of H₂ and H₂O measured by a TDS (thermal desorption spectrometry) analysis.

Evaluation of the gas barrier resistance by the TDS analysis was set as follows:

### (1) H₂:

The gas barrier resistance was determined as A, B, or C based on whether or not the following ion current [A] was exceeded in a temperature range of 300° C. to 450° C. “A” means favorable gas barrier resistance against H₂, “C” means poor gas barrier resistance against H₂, and “B” means an intermediate evaluation between A and C.
Exceeding 1E⁻⁹ [A]: C
Exceeding 5E⁻¹⁰ [A]: B
Less than or equal to 5E⁻¹⁰ [A]: A

### (2) H₂O:

The gas barrier resistance was determined as A, B, or C based on a relationship between the following temperature range and ion current [A]. “A” means favorable gas barrier resistance against H₂O, “C” means poor gas barrier resistance against H₂O, and “B” means an intermediate evaluation between A and C.
Temperature at which the ion current [A] exceeded 1E⁻⁹ [A] was higher than or equal to 300° C. and lower than 350° C.: C
Temperature at which the ion current [A] exceeded 1E⁻⁹ [A] was higher than or equal to 350° C. and lower than 400° C.: B
Temperature at which the ion current [A] exceeded 1E⁻⁹ [A] was higher than or equal to 400° C. and lower than 450° C.: A

After the TDS analysis, a resistance value of the oxide layer of each sample was measured. Those with a resistance value of less than 100 Ωcm were determined as “A”, and those with a resistance value of greater than or equal to 100 Ωcm were determined as “B”. The oxide layer determined as “B” is considered to be difficult to be used as a semiconductor layer.

The measurement was performed as follows.

### (1) Measurement of Ion Current

Analyzer: TDS1200II (manufactured by ESCO, Ltd.)
   Temperature conditions: RT to 500° C. (60° C./min) set as USC temperature
   Sample stage: quartz stage
Quadrupole mass spectrometer
   Ionization procedure: electron ionization
   Measurement mode: SIM mode (Selected Ion Monitoring mode)

### (2) Resistance Measurement

Analyzer: MCP-HT450 (manufactured by Nittoseiko Analytech Co., Ltd.)
   Measurement method: constant voltage application, leakage current measurement method

Table 1 shows content proportions of In, Zn, and Al, and measurement results of each sample. In Table 1, numerical values are each the content proportion of In, Zn, or Al, and “-” indicates that In, Zn, or Al was not contained.

TABLE 1

| | Metal elements contained | | | Gas barrier | | |
|---|---|---|---|---|---|---|
| | [atm %] | | | resistance | | |
| | In | Zn | Al | H₂ | H₂O | Resistance |
| Sample 1 | — | — | 100 | B | C | B |
| Sample 2 | 50 | — | 50 | C | B | B |
| Sample 3 | 60 | — | 40 | C | B | B |
| Sample 4 | 80 | — | 20 | C | C | A |
| Sample 5 | 20 | 50 | 30 | A | A | B |
| Sample 6 | 20 | 30 | 50 | A | A | B |
| Sample 7 | 65 | 35 | — | C | B | A |
| Sample 8 | 49 | 46 | 5 | A | A | A |
| Sample 9 | 49 | 39 | 10 | A | A | A |
| Sample 10 | 65 | 15 | 20 | A | A | A |
| Sample 11 | 100 | — | — | B | B | A |
| Sample 12 | 80 | 20 | — | C | A | A |
| Sample 13 | 65 | 35 | — | C | C | A |
| Sample 14 | 65 | 31 | 4 | A | A | A |

From Table 1, it is revealed that all the results of each of samples 8, 9, 10, and 14 were highly evaluated.

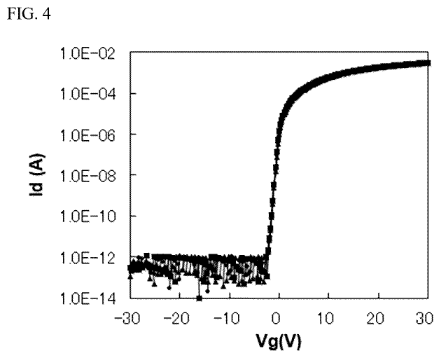

Next, a thin film transistor (sample 15) including an oxide semiconductor layer containing In: 65 atm %, Zn: 35 atm %, and Al: 0 atm %; a thin film transistor (sample 16) including an oxide semiconductor layer containing In: 65 atm %, Zn: 28 atm %, and Al: 7 atm %; and a thin film transistor (sample 27) including an oxide semiconductor layer containing In: 64 atm %, Zn: 35 atm %, and Al: 0.7 atm % were manufactured. Samples 15, 16, and 27 were compared on Id-Vg characteristics, and samples 15 and 16 were compared on the light stress stability. The results are shown in FIGS. 4 to 11.

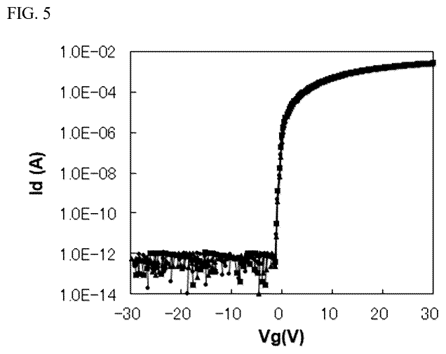

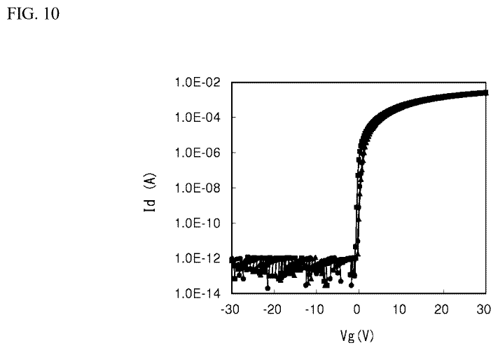

Samples 15, 16, and 27, each provided with a channel length of 10 μm, were compared on Id-Vg characteristics ([drain current (Id)]-[gate voltage (Vg)] characteristics). The Id-Vg characteristics were measured three times for each sample. The results of sample 15 are shown in FIG. 4, the results of sample 16 are shown in FIG. 5, and the results of sample 27 are shown in FIG. 10.

A comparison of FIGS. 4, 5, and 10 indicates that at around Vg 0 [V], an inclination becomes smaller (closer to parallel to the vertical axis) in order of FIG. 4 (sample 15), FIG. 10 (sample 27), and FIG. 5 (sample 16). Accordingly, the transfer characteristics (Id-Vg characteristics) are considered to be able to improve due to containing Al and increasing the content of Al.

Subsequently, samples 15 and 16 were compared on the light stress stability. To evaluate the light stress stability, as a simulation of an environment (stress) at the time of actual liquid crystal panel operation of each sample (thin film transistor: TFT), a stress application test (NBTIS test) was carried out in which the sample was irradiated with light (white light) while negative bias continued to be applied to the gate electrode. Variation (threshold voltage shift amount: ΔVth) in a threshold voltage (Vth) between before and after the stress application was employed as an index of the light stress stability in TFT characteristics. The light stress stability is one of characteristics essential for operation of a liquid crystal display. The NBTIS test was carried out under the following conditions:
Gate voltage: −20 V
Source-drain voltage: 10 V
Substrate temperature: 60° C.
Stress application time period: 2 hours
Light intensity during light stress: 25,000 nits
Light source during light stress: white LED (light emitting diode)

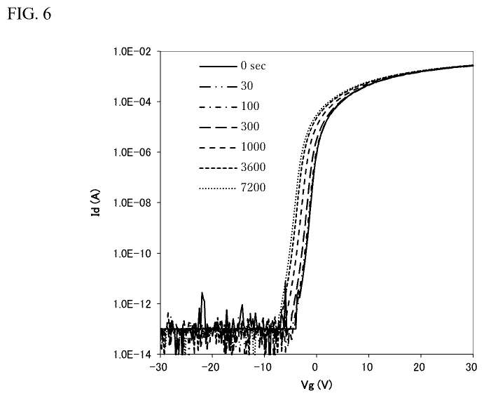

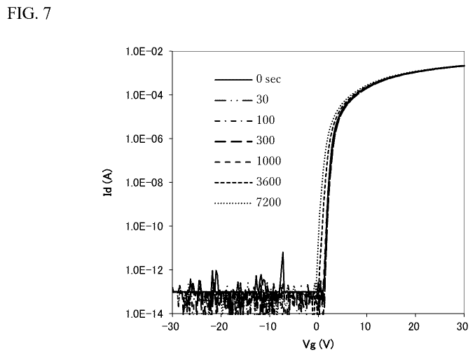

ΔVth of sample 15 was 3.0 [V], and ΔVth of sample 16 was 1.8 [V]. The results of the light stress stability of sample 15 are shown in FIG. 6, and the results of the light stress stability of sample 16 are shown in FIG. 7. A comparison of FIGS. 6 and 7 indicates that at around Vg 0 [V], sample 15 exhibits relatively large variation in the horizontal axis direction, and a relatively large inclination (inclination angle) with respect to the vertical axis direction. Sample 16 exhibits a relatively small variation in the horizontal axis direction, and a relatively small inclination with respect to the vertical axis direction. Accordingly, it is proven that the light stress stability improves due to containing Al. It is to be noted that the numerical values on the left in the graphs (FIGS. 6 and 7) denote time periods of the light stress application. 0 sec is the start of the light stress application, the measurement was carried out after the application for 30 sec, then the measurement was carried out after 100 sec, and further measurements were carried out after 300 sec, 1,000 sec, 3,600 sec, and 7,200 sec, respectively.

A thin film transistor including an oxide semiconductor layer containing In: 65 atm %, Zn: 35 atm %, and Al: 0 atm %; a thin film transistor including an oxide semiconductor layer containing In: 65 atm %, Zn: 28 atm %, and Al: 7 atm %; and a thin film transistor including an oxide semiconductor layer containing In: 64 atm %, Zn: 35 atm %, and Al: 0.7 atm % were used to prepare samples having different channel lengths (lengths of channel regions), and the samples were compared on dependency of the channel length. Table 2 shows the metal elements contained and the channel length of each sample number. It is to be noted that sample 15 described above is the same as sample 19 in Table 2, sample 16 described above is the same as sample 24 in Table 2, and sample 27 described above is the same as sample 30 in Table 2.

TABLE 2

| Channel | Metal elements contained in oxide semiconductor layer | | |
|---|---|---|---|
| length | In/Zn/Al = | In/Zn/Al = | In/Zn/Al = |
| L [μm] | 65/35/0 | 65/28/7 | 64/35/0.7 |
| 5 | sample 17 | sample 22 | sample 28 |
| 8 | sample 18 | sample 23 | sample 29 |
| 10 | sample 19 | sample 24 | sample 30 |
| 20 | sample 20 | sample 25 | sample 31 |
| 50 | sample 21 | sample 26 | sample 32 |

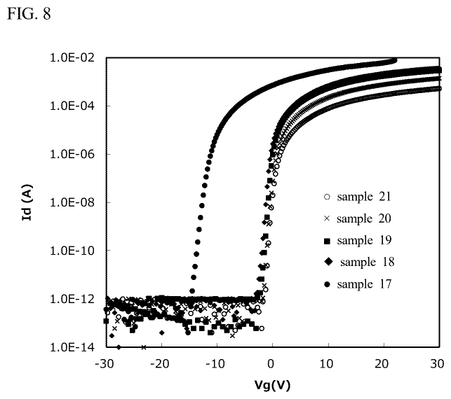

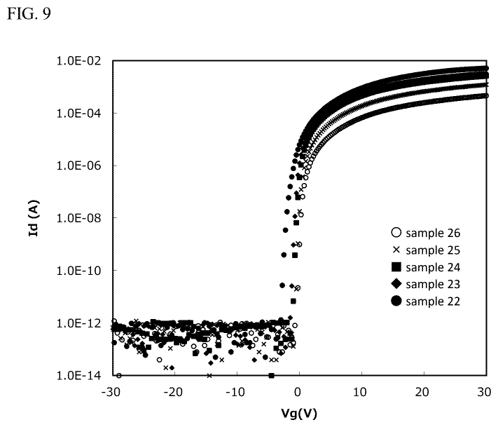

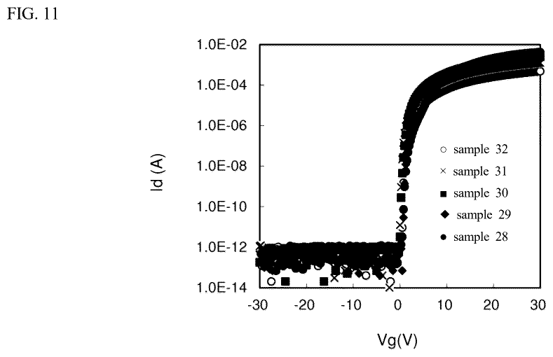

Transfer characteristics of samples 17 to 26 and samples 28 to 32 were measured and compared. The results of samples 17 to 21 are shown in FIG. 8, the results of samples 22 to 26 are shown in FIG. 9, and the results of samples 28 to 32 are shown in FIG. 11.

A comparison of FIGS. 8, 9, and 11 indicates that at around Vg 0 [V], the samples having a channel length of greater than or equal to 8 μm exhibit inclinations that are smaller in order of FIGS. 8, 11, and 9 (closer to parallel to the vertical axis). Accordingly, the transfer characteristics (Id-Vg characteristics) are considered to be able to improve due to containing Al and increasing the content of Al. Furthermore, a comparison of samples 17, 22, and 28 having a channel length of 5 μm indicates that at around Vg 0 [V], sample 17 exhibits a large shift in the horizontal axis direction, whereas samples 22 and 28 exhibit smaller shifts. Accordingly, size reduction of the thin film transistor is considered to be able to be achieved by means of the oxide semiconductor layer containing Al.

### INDUSTRIAL APPLICABILITY

As described above, the method for manufacturing a thin film transistor according to one aspect of the present disclosure enables obtaining a thin film transistor having high operational stability and being suitable for an organic EL display or the like.

### EXPLANATION OF THE REFERENCE SYMBOLS

10, 20, 30: Thin film transistor
11: Substrate
12, 22: Oxide semiconductor layer
13: Protective layer
131: First protective layer
132: Second protective layer
14: Gate insulating layer
15: Gate electrode
16: Source electrode
17: Drain electrode
27: Oxide gas barrier layer

1. A method for manufacturing a thin film transistor on a substrate, the thin film transistor comprising at least: an oxide semiconductor layer; a protective layer; a gate insulating layer; a gate electrode; a source electrode; and a drain electrode, the method comprising:
forming on the substrate, the oxide semiconductor layer comprising In, Zn, and Al as metal elements; and
forming on the oxide semiconductor layer, the protective layer comprising SiN.

2. A method for manufacturing a thin film transistor on a substrate, the thin film transistor comprising at least: an oxide semiconductor layer; an oxide gas barrier layer; a protective layer; a gate insulating layer; a gate electrode; a source electrode; and a drain electrode, the method comprising:
forming the oxide semiconductor layer on the substrate;
forming on the oxide semiconductor layer, the oxide gas barrier layer comprising In, Zn, and Al as metal elements; and
forming on the oxide gas barrier layer, the protective layer comprising SiN.

3. The method for manufacturing a thin film transistor according to claim 2, wherein the oxide semiconductor layer comprises In, Zn, and Al as metal elements.

4. The method for manufacturing a thin film transistor according to claim 1,
wherein
content proportions of the metal elements with respect to a total thereof are as follows:
In: greater than or equal to 40 atm % and less than or equal to 75 atm %;
Zn: greater than or equal to 15 atm % and less than or equal to 45 atm %; and
Al: greater than or equal to 0.5 atm % and less than or equal to 20 atm %.

5. The method for manufacturing a thin film transistor according to claim 1, wherein the oxide semiconductor layer is an amorphous layer.

6. The method for manufacturing a thin film transistor according to claim 3, wherein at least one of the oxide semiconductor layer and the oxide gas barrier layer is an amorphous layer.

7. The method for manufacturing a thin film transistor according to claim 1, wherein the oxide semiconductor layer is formed as a barrier layer against at least one of H₂ and H₂O.

8. The method for manufacturing a thin film transistor according to claim 2, wherein the oxide gas barrier layer is formed as a barrier layer against at least one of H₂ and H₂O.

9. A sputtering target for forming at least one of an oxide semiconductor layer and an oxide gas barrier layer to be used for a thin film transistor, the sputtering target comprising:
In, Zn, and Al as metal elements,
wherein
contents of the In, the Zn, and the Al with respect to a total of all metal elements comprised are as follows:
In: greater than or equal to 40 atm % and less than or equal to 75 atm %;
Zn: greater than or equal to 15 atm % and less than or equal to 45 atm %; and
Al: greater than or equal to 0.5 atm % and less than or equal to 20 atm %.

10. A sintered body for forming the sputtering target according to claim 9.

11. The method for manufacturing a thin film transistor according to claim 2,
wherein
content proportions of the metal elements with respect to a total thereof are as follows:
In: greater than or equal to 40 atm % and less than or equal to 75 atm %;
Zn: greater than or equal to 15 atm % and less than or equal to 45 atm %; and
Al: greater than or equal to 0.5 atm % and less than or equal to 20 atm %.

12. The method for manufacturing a thin film transistor according to claim 3, wherein the oxide semiconductor layer is formed as a barrier layer against at least one of H₂ and H₂O.
